(19) United States
(12) Patent Application Publication
(10) Pub. No.: US 2006/0286392 A1
(43) Pub. Date: Dec. 21, 2006

(54) Housing and method for making the same

(75) Inventors: Chih-Pen Lin, Tu-Cheng (TW); Yong-Ming Li, Shenzhen (CN); Yi-Lin Zhang, Shenzhen (CN); Cheng-Guo Zhang, Shenzhen (CN); Nai-Juan Ren, Shenzhen (CN); Xian-Feng Luo, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FIH Co., LTD, Shindian City (TW)

(21) Appl. No.: 11/396,838

(22) Filed: Apr. 3, 2006

(30) Foreign Application Priority Data
Jun. 17, 2005 (CN) 200510035418.7

(51) Int. Cl. B32B 15/04; B32B 9/00; C23C 14/00

(52) U.S. Cl. 428/457; 428/698; 428/627; 427/402; 204/192.15

(57) ABSTRACT

A housing (100) includes a housing base (10), a chromium film (12), and a chromium carbide film (14). The housing base is made of a material of metal or metal alloys. The chromium film is formed on a surface of the housing base, and the chromium carbide film is formed on a surface of the chromium film. The present invention also provides a method for making the housing.

### BACKGROUND OF THE INVENTION

1. Field of the Invention

The present invention generally relates to portable devices and, more particularly, to a housing for a portable device and a method for making the housing.

2. Discussion of the Related Art

With the development of wireless communication and information processing technologies, portable electronic devices such as notebook computers, mobile phones, digital cameras, and personal digital assistants (PDAs) are now in widespread use. These electronic devices enable consumers to enjoy high technology services anytime and anywhere.

The portable electronic device should have a hard housing for protecting internal elements received therein. A conventional housing for a portable electronic device is made of plastic material, such as acrylonitrile-butadiene-styrene (ABS). Nowadays, housings made of metal or metal alloys, such as stainless steel, aluminum and its alloys, magnesium and its alloys, and titanium and its alloys, are used for the portable electronic devices.

Housings made of stainless steel, aluminum alloy, and aluminum-magnesium alloy may easily be scratched or damaged in daily use, since these materials are relatively soft compared to other metals. Thus, the appearance and attractiveness of the housing can easily be blemished by being scratched or by other damage. Titanium alloy has good hardness, however, the high price of titanium makes it prohibitively expensive for use in portable electronic devices.

Various methods have been devised for treating stainless steel to increase its hardness, including, e.g. nitridation and carburization. In nitridation, the surface of the stainless steel is hardened by forming nitrides. This is done by introducing nitrogen into the stainless steel, usually by heating the stainless steel in gaseous ammonia. In carburization, the outer layer of low-carbon stainless steel is converted into high-carbon stainless steel by contact with a carbonaceous material. Both nitridation and carburization can considerably increase the surface hardness of stainless steel. By carburization, the surface hardness of the treated stainless steel can reach around 800 HV. Whereas by nitridation, a surface hardness of around 600 HV can be reached. Both processes, however, require high temperature treatments for a long period of time. For example, nitridation has to be carried out at a temperature of 524-549° C., and the process takes from 24 to 48 hours to complete. For carburization, the temperature is even higher, with temperatures up to 1,000° C., and takes about 20 hours to complete the process. Therefore, nitridation and carburization have prohibitively low productivity and efficiency, and thus increase the cost of portable electronic device to an unacceptable degree.

In addition, for such metals and metal alloys as aluminum, aluminum alloys, magnesium, magnesium alloys, titanium, and titanium alloys, as these have little or no chromium, neither nitridation nor carburization of a housing made of such material is possible. Metallic hard chromium electroplating is difficult to apply to aluminum and its alloys, magnesium and its alloys, and titanium and its alloys, because these materials oxidize rapidly in electrolytic solutions, and become electrically un-conductive, thus preventing electroplating.

Therefore, a housing which has a high hardness, is desired in order to overcome the above-described problems.

### SUMMARY OF THE INVENTION

In one aspect, a housing includes a housing base, a chromium film, and a chromium carbide film. The housing base is made of metal or metal alloys. The chromium film is formed on a surface of the housing base, and the chromium carbide film is formed on a surface of the chromium film.

In another aspect, a method for making a housing includes the steps of: providing a housing base made of metal or metal alloys; forming a chromium film on a surface of the housing base, and forming a chromium carbide film on a surface of the chromium film.

Other advantages and novel features will become more apparent from the following detailed description when taken in conjunction with the accompanying drawings.

### BRIEF DESCRIPTION OF THE DRAWINGS

Many aspects of the housing can be better understood with reference to the following drawings. The components in the drawings are not necessarily drawn to scale, the emphasis instead being placed upon clearly illustrating the principles of the present housing. Moreover, in the drawings, like reference numerals designate corresponding parts throughout the several views.

FIG. 1 is a schematic view of a housing in accordance with a preferred embodiment.

### DETAILED DESCRIPTION OF THE EMBODIMENTS

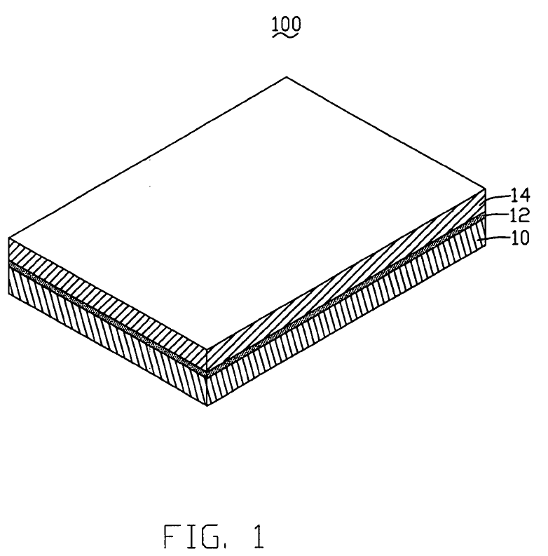

Referring to FIG. 1, showing a portion of a housing 100 in a preferred embodiment, the housing 100 includes a housing base 10, a chromium film 12, and a chromium carbide film 14. The housing base 10 is made of metal or metal alloys, such as stainless steel, aluminum, aluminum alloys, magnesium, magnesium alloys, titanium, and titanium alloys. The chromium film 12 is formed on a surface of the housing base 10, and the chromium carbide film 14 is formed on a surface of the chromium film 12.

The chromium film 12 has an approximate thickness in the range of 0.6-0.8 micron. The chromium carbide film 14 has an approximate thickness in the range of 1.0-2.0 micron. In the chromium carbide film 14, the atom ratio of carbon and chromium is preferably in the range of 0.4-0.5.

The chromium film 12 and the chromium carbide film 14 are formed to improve the surface hardness of the housing 100. The chromium film 12 and the chromium carbide film 14 are both very hard, thus their application increases the surface hardness of the housing 100 by up to 600 HV. The chromium film 12 helps the chromium carbide film 14 adhere to the housing base 10. Furthermore, the chromium film 12 and the chromium carbide film 14 have a stainless-steel-like appearance, which gives the housing 100 an attractive surface appearance.

An exemplary method for making the housing 100 is provided. Firstly, a housing base 10 made of metal or metal alloys is formed by die molding or stamp molding. The metal or metal alloys can be stainless steel, aluminum, aluminum alloys, magnesium, magnesium alloys, titanium, and titanium alloys. Secondly, a chromium film 12 is deposited on the surface of the housing base 10 by sputtering. During sputtering, a chromium metal is used as the sputtering target, and an inert gas is used as the sputtering gas. Thirdly, a chromium carbide film 14 is deposited on the surface of the chromium film 12 by sputtering, this time using a hydrocarbon gas as the sputtering gas. Thereby, a housing 100 is obtained.

The housing 100 can be used in any portable device, such as a cover of a portable electronic device, a watch band/case, or spectacle-frames.

It is believed that the present embodiments and their advantages will be understood from the foregoing description, and it will be apparent that various changes may be made thereto without departing from the spirit and scope of the invention or sacrificing all of its material advantages, the examples herebefore described merely being preferred or exemplary embodiments of the invention.

What is claimed is:

1. A housing comprising:
a housing base;
a chromium film formed on a surface of the housing base; and
a chromium carbide film formed on a surface of the chromium film.

2. The housing as claimed in claim 1, wherein the housing base is made of a metal or metal alloy.

3. The housing as claimed in claim 2, wherein the metal or alloy is selected from the group consisting of stainless steel, aluminum, aluminum alloys, magnesium, magnesium alloys, titanium, and titanium alloys.

4. The housing as claimed in claim 1, wherein the chromium film has an approximate thickness in the range of 0.6-0.8 micron.

5. The housing as claimed in claim 1, wherein the chromium carbide film has an approximate thickness in the range of 1.0-2.0 micron.

6. The housing as claimed in claim 5, wherein an atom ratio of carbon and chromium in the chromium carbide film is in the range of 0.4-0.5.

7. A method for making a housing, comprising the steps of:
providing a housing base;
forming a chromium film on a surface of the housing base; and
forming a chromium carbide film on a surface of the chromium film.

8. The method as claimed in claim 7, the housing base is made of a metal or metal alloy.

9. The method as claimed in claim 8, wherein the metal or metal alloys are selected from the group consisting of stainless steel, aluminum, aluminum alloys, magnesium, magnesium alloys, titanium, and titanium alloys.

10. The method as claimed in claim 7, wherein the chromium film is formed by sputtering, a chromium target is used as the sputtering target.

11. The method as claimed in claim 7, wherein the chromium carbide film is formed by sputtering, a chromium target is used as the sputtering target, and a hydrocarbon gas is used as the sputtering gas.

12. The method as claimed in claim 11, wherein the hydrocarbon gas is one of methane, ethane, and propane.

13. The method as claimed in claim 7, wherein the chromium film has an approximate thickness in the range of 0.6-0.8 micron, the chromium carbide film has an approximate thickness in the range of 1.0-2.0 micron.

14. The method as claimed in claim 13, wherein an atom ratio of carbon and chromium in the chromium carbide film is in the range of 0.4-0.5.
